(19) United States
(12) Patent Application Publication
(10) Pub. No.: US 2020/0124957 A1
(43) Pub. Date: Apr. 23, 2020

(54) PHOTOMASK HAVING REFLECTIVE LAYER WITH NON-REFLECTIVE REGIONS

(71) Applicant: Astrileux Corporation, Richmond, CA (US)

(72) Inventor: Supriya JAISWAL, San Diego, CA (US)

(21) Appl. No.: 16/656,489

(22) Filed: Oct. 17, 2019

Related U.S. Application Data
(60) Provisional application No. 62/746,702, filed on Oct. 17, 2018.

(51) Int. Cl. G03F 1/24; G03F 1/56; B82Y 40/00; H01L 21/027; G03F 1/26

(52) U.S. Cl. CPC G03F 1/24; G03F 1/56; G03F 1/26; H01L 21/0275; B82Y 40/00

(57) ABSTRACT

The present disclosure provides masks suitable for Extreme Ultraviolet (EUV) and X-ray lithography by including a non-reflective region within the reflective multilayer. This non-reflective region replaces a typical absorber layer used to provide the pattern for integrated circuits. New classes of materials and associated components for use in devices and systems operating at ultraviolet (UV), extreme ultraviolet (EUV), and/or soft X-ray wavelengths are described. This disclosure relates to an EUV Photomask Architecture comprising of reflective and non reflective regions eliminating the need for an absorber layer, the effects of shadows on masks, 3D diffraction effects, and defect management. Such a material structure and combination may be used to make components such as mirrors, lenses or other optics, panels, lightsources, photomasks, photoresists, or other components for use in applications such as lithography, wafer patterning, astronomical and space applications, biomedical applications, or other applications.

### CROSS-REFERENCES TO RELATED APPLICATIONS

The present application claims the benefit of U.S. provisional application No. 62/746,702, filed Oct. 17, 2018, the content of which is hereby incorporated by reference in its entirety.

### BACKGROUND OF THE INVENTION

Optical lithography systems are commonly used for fabrication, for example, of devices. The resolving power of such systems is proportional to the exposure wavelength. Thus, shorter wavelengths can improve resolution in fabrication. Extreme ultraviolet lithography (EUVL) uses electromagnetic radiation at extreme ultraviolet (EUV) wavelengths (approximately 120 nanometers to 0.1 nanometers). Accordingly, photons at these wavelengths have energies in the range of approximately 10 electron volts (eV) to 12.4 keV (corresponding to 124 nm and 0.1 nm, respectively). Extreme ultraviolet wavelengths may be generated artificially by devices such as plasma and synchrotron light sources. Using EUV wavelengths for lithography has potential advantages of reducing feature sizes in devices such as semiconductor chips as well as in other applications such as polymer electronics, solar cells, biotech, and medical technologies.

In EUV Lithography systems a Reflective Photomask or mask or reticle is used to transfer the integrated circuit chip architecture onto the wafer. Typically the EUV reflective mask consists of a substrate, reflective layer, capping layer, absorber layer and optionally other layers. The absorber layer is patterned by an e-beam lithography to represent the pattern or the mathematical complement of the pattern of the integrated circuit to be transferred into the wafer.

The selection of reflective materials used in elements of lithography are often severely limited. Traditional material combinations consist of a Molybdenum-Silicon multilayer which theoretically produces up to 67% reflectivity. The Mo—Si layer is used on the mirrors, collector and photomasks in EUV lithography systems. Other traditional multilayer combinations include Tungsten and Boron Carbide, Tungsten and Carbon, collectively referred to as the state of the art.

Typical materials used in an absorber layer pattern may consist of Tantalum Nitride, Tantalum OxyNitride, Nickel or Cobalt or NiAl₃. These materials are chosen to maximize absorption and minimize reflection amplitude or phase change between light reflected from the absorber layer and the multilayer.

There are several known side effects of absorber layer patterns. Absorber layer patterns create a shadow on the reflective layer, known as the 3D shadow mask effect. They also have a finite thickness, typically around 70 nm which has a tendency to trap material defects, particles around 20 nm or so, on the reflective layer which often need to be repaired.

3D mask effects can result in unwanted feature-size dependent focus, imaging aberrations and pattern placement shifts when the absorber layer pattern is transferred to the wafer. In addition, large differences in focus between 1D and 2D features, limit the yield process windows in lithography. Mask shadowing effect is the consequence of the EUV mask absorber height and the non-telecentric, off axis illumination at the mask level, which modulates the intensity projected on to the wafer. Features perpendicular to the direction off illumination (vertical features) are shifted relative to features parallel (horizontal features) to the direction of illumination. At the wafer level, this causes a differential horizontal-vertical critical dimension bias and image shifts. Horizontal-Vertical bias is the systematic difference in linewidth between closely located horizontally and vertically oriented resist features, and is caused by astigmatism, phase error across the pupil, and a difference in best focus.

A phase shifted absorber mask is also used to create a pattern, where adjacent regions are shifted in phase relative to each other, to create a cancellation in the light to achieve the desired pattern. Conventional methods might include reflective/absorbing combinations, or reflective multilayers where the multilayer is etched all the way through to the underlying substrate, and the underlying substrate then absorbs the radiation, or reflective regions adjacent to absorbing regions. This is not effective in overcoming the 3D mask effect, or the shadow mask effect, because the height difference between the top surface and the absorbing surface is the entire thickness of the multilayer stack, or the thickness of the absorber stack.

### BRIEF SUMMARY OF THE INVENTION

In one embodiment, the present disclosure provides an extreme ultraviolet mask, including a substrate; and a reflective layer having a reflective region and a non-reflective region within the reflective layer, wherein the reflective layer includes a bottom surface in contact with the substrate, and a top surface, wherein the reflectivity of radiation in the reflective region is at least 100 times greater than the reflectivity of radiation in the non-reflective region.

### BRIEF DESCRIPTION OF THE DRAWINGS

FIG. 1 shows a mask having a substrate (110) with a reflective multilayer (120) on top of the substrate, with a capping layer (130) and an absorbance layer (140). It shows the typical shadow effect formed by an absorber layer above the reflective plane on the mask. Shadow effect extends to 7 nm for 70 nm thick absorber layer.

FIG. 2 shows a mask of the present disclosure having reflective regions (250) and non-reflective regions (260) within the reflective layer (220). It illustrates a 1-D multilayer on a substrate with a capping layer and non reflective layer. These components form a reflective photomask. In this case, the non reflective layer is submerged in the plane of the multilayer, but does not reach the substrate.

FIG. 3A shows a mask of the present disclosure where the non-reflective region (360) includes a facet (370). FIG. 3B shows the same mask having a transparent material (380) covering the facet (370).

FIG. 4A shows a mask of the present disclosure where the non-reflective region (460) includes a diffraction grating (490).

FIG. 4B shows a mask of the present disclosure where the diffraction grating is at the inclined surface of the facet.

FIG. 5A shows the reflectivity as a function of angle from a molybdenum-silicon multilayer of FIG. 4A with approximately 39 periods. Creating the angular facet involves removing at least 1 period. Hence 39 periods are illustrated instead of 40. At angles >6 from normal incidence (90 degrees) angles >10 degrees from grazing incidence reflectivity is significantly reduce by 2 to 3 orders of magnitude. Light incident at these angles is significantly absorbed. The reflectivity of the reflecting region is 0.67 or −67%.

FIG. 5B shows the diffraction efficiency as a function of wavelength for the first and zero order reflections from a diffraction grating of FIG. 4B where the non-reflective region includes the diffraction grating.

FIG. 6 shows a mask embodiment of the present disclosure having a 3-dimensional photonic crystal as the reflective region (620), and a plasmonic or highly absorbing region adjacent or next to the photonic crystal region. It illustrates a 3D highly reflective photonic crystal where the reflectivity has been detuned in the non reflecting regions patterned by e-beam by depositing a different material e.g. gold, copper, ruthenium either by CVD or ALD, e-beam, electrodeposition or other deposition method, to make a highly non-resonant structure, or absorbing structure with large internal surface area.

FIG. 7A shows the reflectivity as a function of wavelength from a 3-dimensional plasmonic crystal in non-reflective region of FIG. 6. The reflectivity is ˜5×10⁻⁶ and is therefore 5 orders of magnitude smaller than the reflecting region >0.67. The image contrast is ˜1×10⁵.

FIG. 7B shows the reflectivity as a function of angle for the first and zero order reflections from a 3-dimensional photonic crystal of FIG. 6, showing low reflectivity angular range near normal incidence, up to +/−30 degrees from normal incidence.

FIG. 8 illustrates a an angular response of a 6 nm silicon film with high transmission and low reflectivity as a function of angle. It has low reflectivity even at angles close to normal incidence, less than TaON, Ni or Co, NiAL₃, TaN, Au, Ag, and with the multilayer turned off beneath it, it makes a good, transparent, non reflecting region.

FIG. 9A shows a mask embodiment of the present disclosure etched to provide phase shifted reflecting regions to reflect phase-shifted light; FIG. 9B provides a mask embodiment of the present disclosure that provides a partially etched multilayer coating filled with a second set of bilayer pairs having a different period.

FIG. 10 provides a shifted bandgap in a reflective multilayer embodiment.

FIG. 11 provides a phase-shifted region in a non-multilayer embodiment, where the thickness of the top layer is varied.

### DETAILED DESCRIPTION OF THE INVENTION

### I. General

The present disclosure provides new lithography masks for use with extreme ultraviolet and X-ray radiation. These masks incorporate non reflective regions into the reflective multilayer that achieve the image contrast necessary to transfer the image to the wafer through photoresist (a light sensitive imaging material). The use of non-reflective regions to define the pattern of the Integrated Circuit (IC) removes the need for a patterned absorber layer above the reflective multilayer in the integrated mask architecture. By incorporating non-reflective regions within the reflective multilayer, the top surface of the reflective multilayer is substantially planar, so there are essentially no features extending above the top surface of the reflective multilayer that can introduce shadows. The non-reflective regions can be introduced into the reflective layer by modifying selected regions of the top surface of the reflective multilayer to either deflect light into the multilayer rather than to the wafer, or to absorb light. Consequently the mask shadow effect arising from a shadow cast by the finite non-zero height of the absorbance layer relative to the plane of the reflective multilayer is reduced. Further with removal of the absorber layer, or reduced height, 3D waveguideing, image placement errors, 3D diffraction effects, and dead space on the mask are reduced.

The architecture of a typical embodiment of an EUV reflective photomask consists of a substrate, a reflective layer and a capping layer (also known as the EUV mask blank) and an absorber layer. The reflective layer may consist of a multilayer, e.g. Molybdenum Silicon multilayer or other type reflective layer responsible for reflecting EUV radiation. The Ruthenium capping layer is optional, but serves to protect the multilayer from degradation during operation and defects arising from the plasma source and other elements in the lithography system.

The absorber layer is further patterned to represent desired the IC design that needs to be transferred to the wafer. Typically patterning of the absorber layer is achieved by a e-beam lithography process, using e-beam photoresist, e-beam exposure and etching of the absorber layer. This creates finite structures within the absorber layer, which are responsible for selectively blocking EUV radiation in the desired physical location, and allowing light to reflect in others where the absorber structure is absent.

Absorber layer selection depends on a number of parameters, including thickness, material n and k value, which represent the real and imaginary part of the refractive index at the desired wavelength, top surface reflection amplitude and overall absorption amplitude. The phase change between light reflected from the multilayer and light reflected from the absorber layer also needs to be minimized, as does the shadow on the reflective layer which minimizes the effective reflective area and creates a dead space. Absorber layers of finite thickness create waveguiding effects, another manifestation of the 3D mask effect, which are undesirable.

Competing goals exist in the material selection of the absorber layer. On one hand complete absorption is desired to prevent light transferring into the reflective layer below, which would then be undesirably reflected. This could be achieved by very thick absorber structures. However, thicker absorber structures produce larger shadows on the reflective portion of the mask, more wave-guiding and increase the propensity of defect trapping. More absorbing materials may also be used, e.g. gold and silver, but typically result in more top surface reflection from the absorber layer which is undesirable. TaN represents one of the better material selections for absorber layer, which effectively compromises absorption and top surface reflection with a finite of thickness of 70 nm. Ni and Co, and various combinations and compounds thereof are also materials of choice.

In lithography the finite absorber layer pattern deteriorates on wafer performance and the quality of the pattern transferred to the wafer. Phase differences create contrast loss, shifts in depth of focus, and the Bossung Curve (CD v depth of focus), Horizontal and Vertical Bias and resolution. Therefore several approaches already exist to reduce the thickness of the absorber layer and phase difference. None of these completely remove the shadow effect, or prevent waveguiding or defect trapping.

This disclosure relates to an EUV photomask architecture without the use of an absorber layer. Specifically the reflective layer or reflective coating is patterned to provide both reflection in certain physical locations and to turn off or suppress reflectivity in other selective physical locations. Turning off reflectivity is distinguished from transmission or absorption explicitly, and relates to removing or extinguishing surface reflection in the top surface or plane of reflection. Turning off reflectivity is more desirable than having an absorption layer, as it achieves an improved image contrast without waveguiding, shadowing or defect trapping, and increases reflectivity of the multilayer. In physical terms, turning off reflectivity here can be achieved by multiple internal reflections, scattering or absorption within the multilayer, so the light never really emerges in the 0th order reflection from the incidence plane, or top surface plane. Since the internal absorption, scattering or, internal reflection is high, within a high surface area nanostructure, the light never really reaches the substrate, but is lost sideways in the structure.

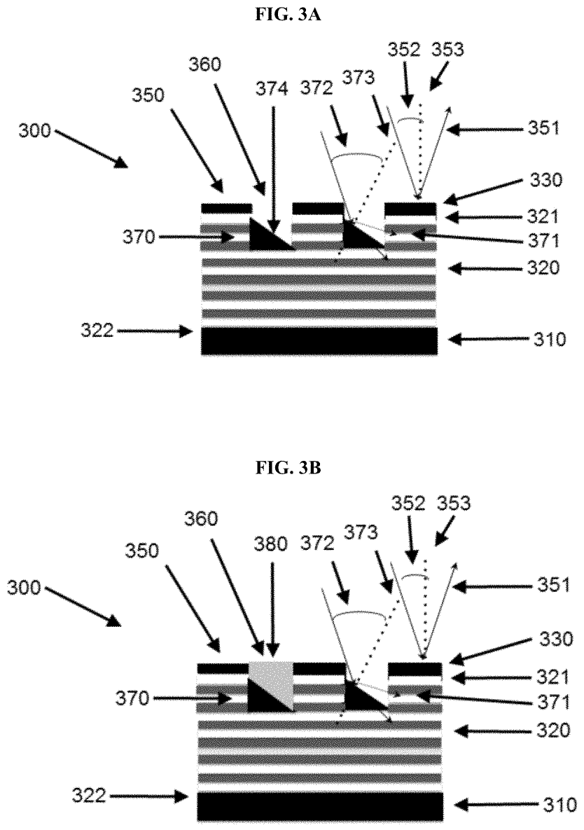

Turning off reflectivity can be achieved by detuning the resonance of a particular photonic, plasmonic structure, multilayer or other reflector. For example the resonance of a Mo—Si multilayer can be detuned by selecting a different angle of incidence on the surface of the reflector, where the angle of incidence is greater than 6 degrees from the normal incidence. This is created by changing the angle of the normal of the surface to the incident light, and appears as angular facet in the structure as shown in the FIG. 3A. In fact any light being reflected by a facet, has a 0th order of reflection that at wide enough angle to be blocked by the walls of the reflecting part of multilayer, and so subsequently undergoes a secondary reflection at wide angle, with low reflectivity, and further multiple internal reflections, and never really emerges from the multilayer with any significant reflectivity. Since each reflection is of the order 10⁻³, two or more internal reflections will give a non reflecting region of 10⁻⁶. This can give a high image contrast of the order of 10³ or higher (up to 10⁵ depending on the facet angle). The state of the art image contrast using TaN absorber layer is 10². The typical length of a non reflecting region (horizontal) may be 20 nm depending on the desirable critical dimension of a particular lithography node.

Angular facets or blazing, or blazed angle approaches, can be fabricated by several methods including e-beam patterning in photoresist, exposure, followed by etching. Etching can include wide angle etching, isotopic etching, rotating substrate, tilted substrate etc, atomic layer etch, reactive ion etch, ion beam etch, plasma etching, inductive coupled plasma etching, holographic patterning, and Voltage biased etching or other isotropic or anisotropic etches, including chemical and wet etching.

The architecture may optionally be filled with silicon and planarized e.g. chemical mechanical polishing. Silicon has a top surface reflectivity of 10⁴ near normal incidence. Silicon is highly transmissive, and so the underlying reflective layer needs to be turned off to create a non reflective region. One approach is to have angle facet in the multilayer to achieve internal dissipation of the light. Silicon prevents unwanted defect particles landing in the trough of the non reflective region. However, since the depth is very shallow anyway (˜6-7 nm), and the region is angle faceted defects are unlikely to deposit. As an alternative to silicon, aluminum, boron carbide (B₄C) or strontium may also be used.

If the angular facet has an angle of 20 degrees or more, the image contrast is at least 10³ and the etch depth is approximately 6 nm. This prevents defect trapping on the reflective part of the mask and since the non reflecting part is below the reflective part, no shadows are formed. Furthermore, the depth is too shallow (less than a wavelength) to create any potential deep wave guiding effects or 3D diffraction effects. The facet angle should ideally be greater than 6 degrees (assuming the incident light on the mask is 6 degrees from the reflecting plane surface normal), and not equal to 42 degrees (+/−5 degrees), as this would either send the zeroth order of reflection back along its incident angle without the opportunity for secondary reflection, or at an angle of 90 degrees (horizontal) to the reflecting plane which has a reflection coefficient close to 1 respectively. Facet angles can slope upwards or downwards.

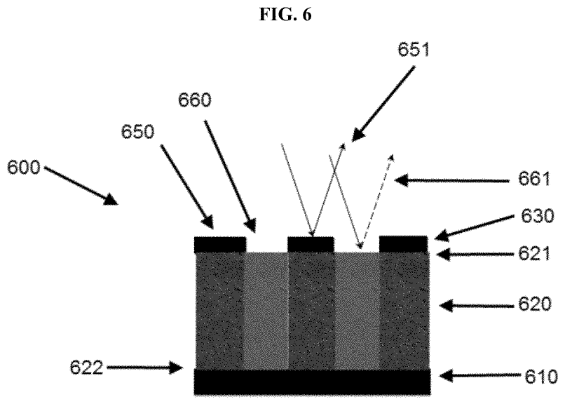

In FIG. 6, 3D reflective structures, e.g. photonic, plasmonic, metamaterial or metallo dielectric structures, periodic or porous structures, reflectivity can be suppressed by destroying the photonic bandgap, or detuning the resonance. For example a periodic structure may be detuned by changing the periodicity of the reflective structure, the pore size or the material n and k value, or the angle of incidence of the incoming radiation on the surface, or the surface normal angle with respect to the incoming radiation. Detuning the resonance in 1D structures can also be achieved by changing the thickness or period of the individual films in a multilayer. The ratio of each of material counterpart to the period is known as the fill factor.

In this embodiment a detuned 3D photonic structure e.g. a 3D porous structure is highly absorptive due to the large internal surface area, and therefore provides significant absorption and image contrast to the reflecting part of the mask of the order of 10⁵. Materials of the non reflecting part may be high k materials such as gold, silver, platinum, copper, nickel, cobalt, iron, manganese, zinc, etc. Nanostructured materials have very little surface reflection. Each of these materials have very short attenuation lengths, some shorter than TaN and TaON.

Image contrast is defined as the ratio of the intensity of light reflected from the non-reflective region to light to the intensity of light reflected from the reflective region. Image contrast may also be described as extinction co-efficient. It represents the effectiveness of the non-reflective region to suppress reflected light relative to the reflective region, and provide a sharp edge for patterning the wafer, enabling high resolution and pattern fidelity.

This disclosure describes the use of a non reflective region in an EUV or X-ray mask, for EUV lithography applications and other applications.

In certain embodiments, the disclosure relates to an element that can be used in a light exposure system, wherein the system or subsystem includes a light source to transmit light having a wavelength.

In another embodiment, the disclosure relates to an element that can be used in a light exposure system containing a photomask, mirror or lens, substrate element. The system or subsystem can include a light source to transmit light having a wavelength. The element can include a material having plurality of structural features or one or more material combinations.

### II. Definitions

The abbreviations used herein have their conventional meaning within the chemical and lithographic arts.

“Substrate” refers to any material capable of supporting the multilayer of the present disclosure. Representative substrates can be metals, metal alloys, semiconductors, composites, polymers, glass, and others.

“Reflective layer” refers to a material that substantially reflects extreme ultraviolet (EUV) radiation, such as radiation less than 250 nm to less than 10 nm. The reflective material can also reflect X-ray radiation. Materials suitable for reflective layers of the present disclosure include Molybdenum/Silicon composite, among others. The reflective layer can include reflective regions and non-reflective regions, i.e., regions that do not substantially reflect EUV and X-ray radiation.

“Facet” refers to a shallow depression in the top surface of the reflective layer that is sufficiently angled from the top surface to reflect light into the multilayer rather than to the wafer.

“Angle of incidence” refers to the angle between the incoming radiation and the normal or normal incidence, the line perpendicular to the surface at the point of incidence. The angle of incidence can be any suitable angle. The angle of incidence for EUV lithography can be 6°.

A “3-dimensional reflective photonic crystal” refers to a three dimensional engineered material architecture that has features with a periodicity, aperiodicity, or quasi-periodicity in three dimensions, and produces a photonic bandgap: a set a frequencies or wavelengths where light is forbidden to propagate through the material and subsequently reflected. (U.S. Pat. No. 9,322,964.)

“Metal” refers to elements of the periodic table that are metallic and that can be neutral, or negatively or positively charged as a result of having more or fewer electrons in the valence shell than is present for the neutral metallic element. Metals useful in the present disclosure include the alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Mg, Tc, Ru, Rh, Pd, Ag, Cd, La, Hf, Ta, W, Re, Os, Ir, Pt, Au, Hg, Al and Ac. Post-transition metals include Al, Ga, In, Tl, Ge, Sn, Pb, Sb, Bi, and Po. Rare earth metals include Sc, Y, La, Ce, Pr, Nd, Sm, Eu, Gd, Tb, Dy, Ho, Er, Tm, Yb and Lu. One of skill in the art will appreciate that the metals described above can each adopt several different oxidation states, all of which are useful in the present disclosure. In some instances, the most stable oxidation state is formed, but other oxidation states are useful in the present disclosure. Compounds of transition metals may also be used e.g. TiN. Metals and compounds may be deposited by e-beam deposition, thermal evaporation, PVD, CVD, ALD, or PECVD, MBE, sputtering or ion beam deposition.

“Transparent material” refers to a material that is transparent to EUV radiation. Representative transparent materials include silicon and silicon dioxide, graphene, carbon nanotubes, gases, H₂, He, Argon, N₂, silicides, silicene, and Bucky balls.

“Capping layer” refers to a layer on top of the reflective multilayer that is used to protect the reflective multilayer from particles that can accumulate on the mask over time. Any suitable material can be used in the capping layer of the present disclosure, such as ruthenium and other transition metals.

“Absorbance layer” or “absorbing layer” refers to a layer on top of the reflective multilayer, and typically on top of the capping layer, that absorbs EUV radiation. The absorbance layer covers only selected portions of the reflective multilayer. Thus, an image contrast is formed between the regions of the mask having the absorbance layer and those without, enabling the transfer of an image to the wafer.

“Diffraction grating” refers to an optical component having a periodic structure in one, two or three dimensions, that diffracts light from a single direction into multiple directions. The diffraction grating can be made of any suitable material.

“Image contrast” is defined as the ratio of the intensity of light reflected from the reflective region to light to the intensity of light reflected from the non reflective region.

“Phase difference” refers to the difference between the phase of the reflected wavefront emanating from the reflective region and the phase of the wavefront emanating from the non reflective or absorbing region.

### III. Extreme Ultraviolet Lithography Mask

The present disclosure is drawn to a mask for extreme ultraviolet (EUV) and X-ray lithography that avoids problems with mask shadowing by avoiding use of an additional absorber layer and incorporating into the reflective multilayer a set of one or more non-reflective regions. The presence of the non-reflective regions in the reflective multilayer provide the necessary image contrast to transfer the image from the mask to the wafer. In some embodiments, the present disclosure provides an extreme ultraviolet mask, including a substrate; and a reflective layer having a reflective region and a non-reflective region within the reflective layer, wherein the reflective layer includes a bottom surface in contact with the substrate, and a top surface, wherein the reflectivity of radiation in the reflective region is at least 100 times greater than the reflectivity of radiation in the non-reflective region. This is also known as image contrast. The non reflective regions may reflect a small amount of light that is out of phase with the reflective regions. This means that light emanating from these two regions cancel to produce no net light. The phase difference from these two regions can be tuned to be equal to zero.

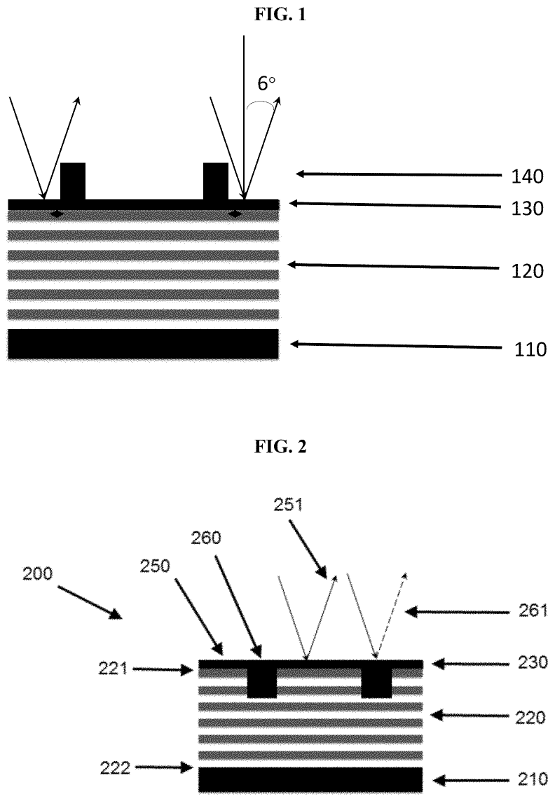

The state of the art is described in FIG. 1. A TaN or TaON absorber layer is deposited on the EUV mask blank (Multilayer+Ru Capping Layer) and patterned via e-beam lithography. The 70 nm layer is absorbing, and creates a 7 nm shadow, or dead region. It transmits 8% of the incident light at 13.5 nm. It also introduces a Pi phase shift for cancellation of the incoming light. Any reflected light from the absorber layer can be approximately calculated by the following formula:

Transmission Efficiency(absorber layer)²×Reflectivity of Multilayer(0.67)˜4×10⁻³ The Image contrast can be calculated by Multilayer Reflectivity/Absorber Reflectivity=˜10².

FIG. 2 shows a mask of the present disclosure (200) having a substrate (210) and a reflective layer (220), where the reflective layer includes a reflective region (250) and a non-reflective region (260), where the reflective layer has a bottom surface (222) in contact with the substrate, and a top surface (221). The reflectivity of the radiation in the reflective region (251) is at least 100 times greater than the reflectivity of radiation in the non-reflectivity region (261). The mask can also include a capping layer (230).

The substrate can include any suitable material. For example, the substrate material can include, but is not limited to, metal, metal alloys, semiconductors, composites, polymers, glass, and combinations thereof. In some embodiments, the substrate can be a metal, a metal alloy, a semiconductor, a composite, a polymer, a glass, and combinations thereof. In some embodiments, the substrate can be a semiconductor. In some embodiments, the substrate can be glass. In some embodiments, the substrate can be silicon dioxide, fused silica, quartz, Zerodur™, ultra low thermal expansion substrates.

The reflective layer can include any suitable material capable of substantially reflecting extreme ultraviolet or X-ray radiation. Representative materials for the reflective layer include, but are not limited to, molybdenum, silicon, niobium, technetium, zirconium, ruthenium, beryllium, tungsten, boron carbide, carbon, 3-dimensional reflective photonic crystal and others. The reflective layer can be a single layer of one material, or can be alternative layers of several materials, a multilayer.

The reflective layer can be a single layer, or have from 2 to 1000 alternating layers. In some embodiments, the reflective layer can be a single layer. In some embodiments, the reflective layer can be a multilayer.

The reflective layer can be of any suitable thickness sufficient to reflect EUV or X-ray radiation. For example, the reflective layer can be from 50 to 1000 nm in thickness, or from 100 to 750 nm, or from 100 to 500 nm, or from 200 to 400 nm. The reflective layer can have a thickness of about 50 nm, or about 100, 150, 200, 250, 300, 350, 400, 450, 500, 600, 700, 800, 900, or about 1000 nm. In some embodiment, the reflective layer can have a thickness of about 300 nm.

The non-reflective regions of the reflective layer can be of any suitable width and length to provide the desired image in the wafer. The non-reflective regions of the reflective multilayer can be of any suitable depth into the reflective layer. For example, the non-reflective portion can extend just a few nanometers into the reflective layer from the top surface of the reflective layer, or extend through the reflective layer to the substrate. In some embodiments, the non-reflective regions are from about 0 to about 100 nm deep from the top surface of the reflective layer, or from 1 to about 50 nm, or from 1 to about 25 nm, or from 1 to about 20 nm from the top surface of the reflective layer. In some embodiments, the non-reflective regions extend through the reflective layer to the substrate.

The difference in reflectivity between the reflective regions and non-reflective regions of the reflective layer create an image contrast sufficient to transfer the image from the mask to the wafer. The image contrast can be determined by dividing the reflectivity of the reflective region by the reflectivity of the non-reflective region, providing an image contrast of at least 10, or at least 50, 100, 200, 300, 400, 500, 1000, 2000, 3000, 4000, 5000, or at least about 10,000. In some embodiments, the reflectivity of radiation in the reflective region is at least 100 times greater than the reflectivity of radiation in the non-reflective region. In some embodiments, the reflectivity of radiation in the reflective region is at least 1000 times greater than the reflectivity of radiation in the non-reflective region. In some embodiments, the reflectivity of radiation in the reflective region is at least 10,000 times greater than the reflectivity of radiation in the non-reflective region.

The mask of the present disclosure is suitable for use with extreme ultraviolet and X-ray radiation. Extreme ultraviolet (EUV) radiation includes radiation from less than 250 nm to less than 10 nm, or from about 193 nm to less than 10 nm, or from about 124 nm to about 10 nm, or from about 20 nm to about 10 nm. In some embodiments, the radiation has a wavelength from 250 nm to 1 nm. In some embodiments, the radiation has a wavelength from 193 nm to 1 nm. In some embodiments, the radiation has a wavelength from 124 nm to 10 nm. In some embodiments, the radiation has a wavelength of about 13.5 nm.

The non-reflective regions of the reflective layer can include a facet, a diffraction grating, a 3-dimensional photonic crystal, or combinations thereof.

In some embodiments, the light is incident on the surface normal at an angle greater than 6 degrees. In some embodiments, the surface normal is at least 6 degrees to the surface normal of the reflective region.

In some embodiments, the extreme ultraviolet mask also includes an angular faceted structure.

In some embodiments, the reflectivity, optical response is detuned away from the peak resonance, by periodic changes, angular changes or fill factor. In some embodiments, absorption is achieved by a non reflecting layer within the reflective layer, below the plane of the surface, such that no absorber layer is present.

In some embodiments, the reflective coating is a multilayer coating. In some embodiments, the coating includes molybdenum, niobium, or ruthenium.

In some embodiments, the top layer is silicon or silicon dioxide.

In some embodiments, the mask is used in conjunction with a pellicle.

### A. Facets

The non-reflective regions of the mask of the present disclosure can include facets, inclined surfaces, that direct the incident radiation into the reflective layer, at an angle outside the multilayer's main reflectivity range instead of towards the wafer. In some embodiments, the non-reflective region comprises a facet at the top surface of the reflective layer, or into the reflective region.

FIG. 3A shows a mask of the present disclosure (300) having a substrate (310) and a reflective layer (320), where the reflective layer includes a reflective region (350) and a non-reflective region (360), where the reflective layer has a bottom surface (322) in contact with the substrate, and a top surface (321). The non-reflective region includes a facet (370) at the top surface of the reflective layer. The facet includes an inclined surface (374), that establishes a first angle of incidence (372) between the incident radiation and the normal incidence (373) for the non-reflective region, such that the reflected radiation (371) is reflected into the reflective layer. The reflective region has a second angle of incidence (352) between the incident radiation and the normal incidence (353) for the reflective region, such that the reflective radiation (351) is reflected towards the projection optics to the wafer. The mask can also include a capping layer (330).

The facets of the present disclosure direct radiation into the reflective layer by having a larger angle of incidence than for the radiation incident on the reflective regions of the reflective layer. For example, EUV radiation incident to a mask can have an angle of incidence of about 6° from the normal incidence, while EUV radiation incident to the facet can have an angle of incidence greater than 6° from the normal incidence. The EUV radiation incident to the facet can have an angle of incidence of greater than 6° from the normal incidence, or greater than 10, 11, 12, 13, 14, 15, 16, 17, 18, 19, 20, 21, 22, 23, 24, or 25° from the normal incidence. In some embodiments, the facet comprises a first angle of incidence that is greater than a second angle of incidence for the reflective region. In some embodiments, the first angle of incidence is greater than 6 degrees from the normal incidence for the reflective region. In some embodiments, the first angle of incidence is greater than 10 degrees from the normal incidence for the reflective region. In some embodiments, the first angle of incidence is 20 degrees from the normal incidence.

The facets of the present disclosure include an inclined surface having a first end and a second end, where the second end is below the first end, thus forming the inclined surface. The inclined surface of the facet is the hypotenuse of a right triangle. When the first end of the inclined surface is at the top surface of the reflective layer, the angle between the inclined surface of the facet and the top surface of the reflective layer forms the facet angle, such that the first leg of the triangle is adjacent to the facet angle, and the side of the triangle opposite the facet angle is the third leg of the triangle.

The facet can have any suitable facet angle. For example, the facet angle can be at least 5°, or at least 6, 7, 8, 9, 10, 11, 12, 13, 14, 15, 16, 17, 18, 19, 20, 25, 30, 35, 40, or at least 45°. In some embodiments, the facet angle can be at least 10°. In some embodiments, the facet angle can be at least 20°.

The facet can be at the top surface of the reflective layer, such that the first end of the inclined surface is at the top surface of the reflective layer. The facet can also be within the reflective layer, such that both the first end and second end of the inclined surface are at least 5 nm below the top surface of the reflective layer. For example, the first end and second end of the inclined surface can be at least 5 nm below the top surface of the reflective layer, or at least 10, 15, 20, 25, 30, 35, 40, 45, or at least 50 nm below the top surface of the reflective layer. In some embodiments, the facet inclined surface comprises a first end and a second end wherein the second end is between 1 nm and 10 nm below the first end.

The reflective layer can include any suitable material capable of substantially reflecting extreme ultraviolet or X-ray radiation. Representative materials for the reflective layer include, but are not limited to, molybdenum, silicon, beryllium, tungsten, boron carbide, carbon, and others. The reflective layer can be a single layer of one material, or can be alternative layers of several materials, a multilayer. In some embodiments, the reflective layer includes multilayers of molybdenum and silicon, tungsten and boron carbide, or tungsten and carbon. In some embodiments, the reflective layer includes multilayers of molybdenum and silicon. In some embodiments, the reflective layer includes multilayers of molybdenum and beryllium. Multilayers are typically deposited by sputtering, magnetron or cathode sputtering, ion beam deposition or ion assisted deposition, chemical vapor deposition, plasma enhanced chemical vapor deposition, pulsed vapor deposition, molecular beam epitaxy or epitaxial growth or e-beam deposition. A typical EUV multilayer consists of alternating layers of Molybdenum and Silicon, or Ruthenium and Silicon or Niobium and Silicon, on a Silicon or Fused silica substrate. The alternating layers form a Bragg reflector where light is coherently reflected in phase at each interface between consecutive layers to build up reflectivity. Typically 40 bilayer pairs are used in Molybdenum Silicon. Spiller, Eberhard A. “Low-loss reflection coatings using absorbing materials.” U.S. Pat. No. 3,887,261. 3 Jun. 1975.

A process for making a faceted angle may be:

1) Create an EUV mask architecture by deposited reflective coating on substrate, optionally followed by capping layer, e.g. Ruthenuim.
2) Coat top surface with photoresist or e-beam resist, e.g. through spin coating, vapor deposition, spraying or dip coating.
3) Use e-beam or optical lithography direct write to pattern resist into reflecting and non reflective regions, representing IC pattern
4) Use etching process to create a facet angle in the underlying reflective coating, e.g. tilted reactive ion etch, anisotropic or voltage bias etch, or etching followed by wide angle deposition
5) Optionally deposit silicon or ruthenium
6) Remove photoresist or e-beam resist.
7) Optionally planarize top surface by chemical mechanical polishing is silicon is deposited
8) Optionally deposit ruthenium capping layer afterwards if not already deposited in 1)
9) Optionally use grayscale lithography via e-beam or optical to control the exposure dose to pattern the resist with a depth profile in the form of the faceted angle.

The facets can optionally be filled with a material transparent to EUV and X-ray radiation to make the top surface of the reflective layer substantially planar. FIG. 3B shows the transparent material (380). Representative materials include silicon, silicon dioxide, aluminum, boron carbide, aluminum, strontium, and mixtures thereof. In some embodiments, the facet is filled with a transparent material so that the top surface of the reflective layer is substantially planar. In some embodiments, the transparent material comprises silicon, silicon dioxide, aluminum, boron carbide, aluminum, strontium, or mixtures thereof. In some embodiments, the transparent material comprises silicon, silicon dioxide, or mixtures thereof. The transparent material may be deposited by RF or DC sputtering, magnetron sputtering, ion beam deposition, e-beam deposition, or vapor deposition, chemical vapor deposition, plasma enhanced chemical vapor deposition, molecular beam epitaxy, epitaxial growth, followed by chemical mechanical polishing to achieve planarization.

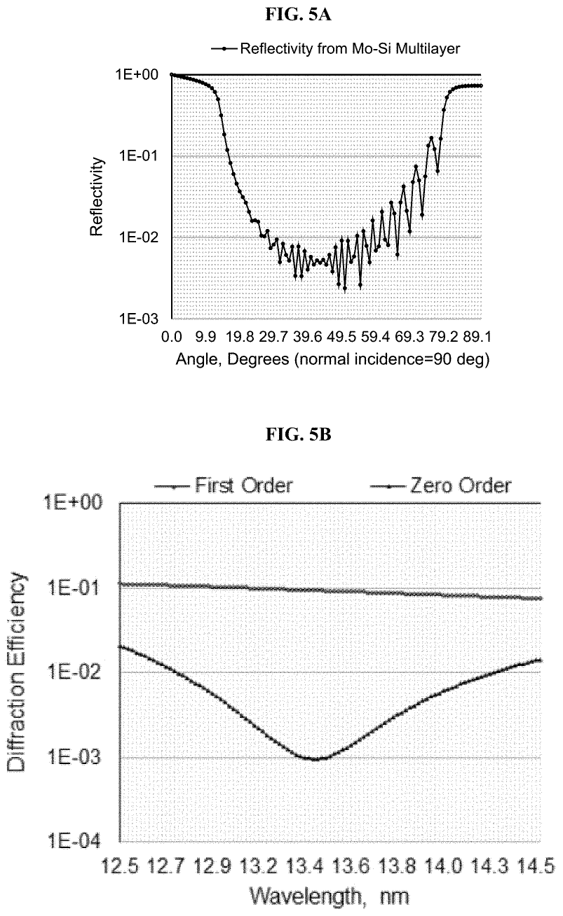

A faceted angular structure made from an EUV refractive material can be embedded in place of an absorber layer. Examples of EUV refractive materials are Ruthenium, Rhenium, Palladium, Silver, Technicium, or any material where the delta of the real part of the refractive index from 1 is greater than 0.1. Such materials bend the light before entering the multilayer to angles greater than 6 degrees. In fact a typical angular facet may be 20-40 degrees and, the light may enter the multilayer from an angle 6-15 degrees, where the multilayer is not especially reflective (˜10⁻² to 10⁻³) (FIG. 5A). In fact any light that does exit from the facet angle is incident in the wall of the adjacent reflecting region, and dissipated, and so never really emerges from the non reflecting region. Additionally a faceted angular structure may be placed in the multilayer, coated with an EUV refractive material. A faceted angle approach reduces the depth of the non reflective region relative to the reflective region, and therefore reduces the 3D diffraction effect, and the shadow on the mask. Image contrast between the reflective and non reflective region is ˜10³ to 10⁴.

### B. Diffraction Grating Embodiments

The present disclosure also provides an EUV mask where the non-reflective region includes a diffraction grating to diffract light into the reflective layer. In some embodiments, the non-reflective region comprises a diffraction grating at the top surface of the reflective layer.

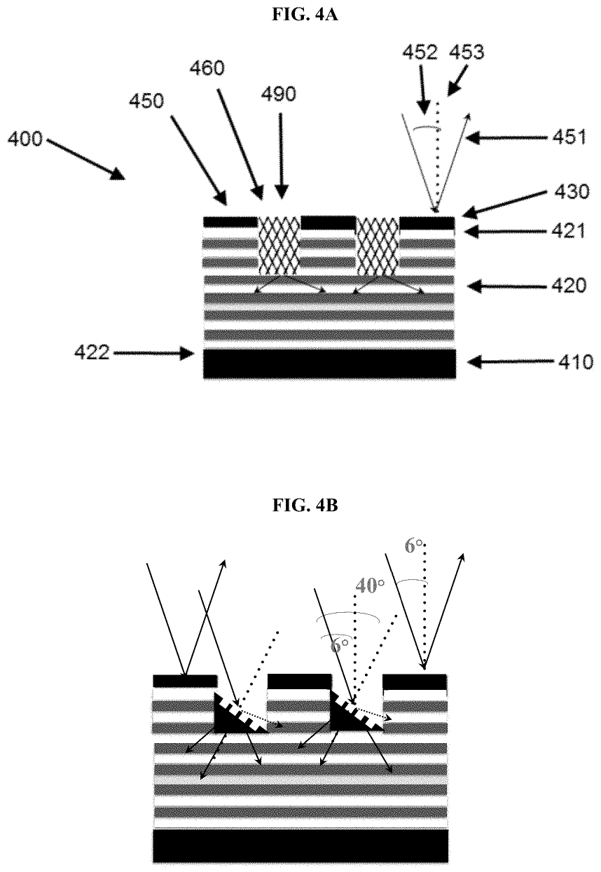

FIG. 4A shows a mask of the present disclosure (400) having a substrate (410) and a reflective layer (420), where the reflective layer includes a reflective region (450) and a non-reflective region (460), where the reflective layer has a bottom surface (422) in contact with the substrate, and a top surface (421). The non-reflective region includes a diffraction grating (490) at the top surface of the reflective layer. The reflective region has a second angle of incidence (452) between the incident radiation and the normal incidence (453) for the reflective region, such that the reflective radiation (451) is reflected towards the wafer. The mask can also include a capping layer (430).

The diffraction grating can be embedded within the non-reflective region, or sit on top of the non-reflective region. In some embodiments, the diffraction grating is embedded within the non-reflective region. In some embodiments, the diffraction grating is on top of the non-reflective region.

The diffraction grating can be one, two or three-dimensional in nature. In some embodiments, the diffraction grating is one-dimensional, two-dimensional or three-dimensional. In some embodiments, the diffraction grating is one-dimensional. In some embodiments, the diffraction grating is two-dimensional. In some embodiments, the diffraction grating is three-dimensional.

The diffraction grating can be prepared from any suitable material, including metals, metal oxides, and other materials. The diffraction grating can be prepared from the same material as the reflective layer, or a different material. The diffraction grating can be prepared from the same material as the non-reflective region, or a different material. In some embodiments, the diffraction grating includes at least one component of molybdenum, niobium, ruthenium, platinum, palladium, rhenium, osmium, silver, nickel, cobalt, copper, nickel, gold, copper, tungsten, tantalum oxide or tungsten oxide, or NiAl₃. In some embodiments, the diffraction grating is prepared from the same material as the reflective layer. In some embodiments, the diffraction grating is prepared from the same material as the non-reflective region.

A diffraction grating is prepared using either optical lithography, e-beam lithography, grayscale lithography or etched rulings. In e-beam (electron beam) or optical lithography a sensitive material such as photoresist or e-beam resist material is prepared on the surface and then patterned via exposure to a laser source or electron beam source. The resist is then cross linked, and unexposed regions are removed via wet chemical processing. The pattern resist region acts as a soft mask, and via an etching process the pattern is transferred into the wafer. A blazed grating, e.g. with a saw tooth profile may be created using grayscale lithography where the dose of the exposure beam is varied as a during exposure to create a depth profile in the resist. Alternatively the blazed grating may be produced by non isotropic etching, or by orienting the grating at an angle. The diffraction grating may also be created by a combination of etching, self assembly and deposition for 3D gratings, or through an EUV/DUV lithography and directed self assembly combination.

The non-reflective region of the present disclosure can include both a facet and a diffraction grating. In some embodiments, the non-reflective region further comprises a facet. When both a facet and a diffraction grating are present in the non-reflective region, the diffraction grating can be embedded within the inclined surface of the facet, or on top of the inclined surface of the facet. In some embodiments, the facet comprises an inclined surface having a diffraction grating embedded within the inclined surface. In some embodiments, the facet comprises an inclined surface having a diffraction grating on top of the inclined surface.

FIG. 4B shows a mask of the present disclosure having both a facet (470) and a diffraction grating (490) at the inclined surface (474) of the facet.

In FIG. 4A the embedded diffraction grating couples light into the facet and redistributes to several well defined orders which are at off-angles which are outside the angular bandwidth of the diffraction grating. A diffraction grating may be placed on top of or embedded within the ML mask structure, to suppress the zero order. The diffraction grating may be a uniform or non uniform grating, and in 1, 2, 3 dimensions. A non uniform grating achieves higher dispersion. Since the zero order is suppressed, most of the light is re-channeled into +/−1 orders, which enter the ML at incidence angles greater than 6 degrees, where the reflection is significantly diminished (FIG. 5A). The Diffraction efficiency (DE) of each order is shown in FIG. 5B Reflectivity Rₙ, n>0, is ˜10⁻² or 10⁻³.

Reflectivity(non refl. region)=(ΣₙDEₙ2Rₙ)

Therefore the reflectivity from the non reflecting region is Reflectivity ˜10⁻⁴ to 10⁻⁵. Image contrast: Reflectivity from reflecting region/reflectivity from non-reflecting region ˜10³ to 10⁴.

### C. 3-Dimensional Photonic Crystal

The present disclosure also provides an EUV mask where the non-reflective region is chemically distinct from the reflective regions of the reflective layer, such as by deposition of an EUV absorbing material in the non-reflective regions. In some embodiments, the reflective layer comprises a 3-dimensional reflective photonic crystal, wherein the reflective region comprises a first metal, and wherein the non-reflective region comprises a second metal. In some embodiments, the reflective layer comprises a 3-dimensional reflective photonic crystal, wherein the reflective region comprises for example a first metal, and wherein the non-reflective region comprises for example a second metal, a highly absorbing region, e.g. a plasmonic crystal.

FIG. 6 shows a mask of the present disclosure (600) having a substrate (610) and a reflective layer (620) of a 3-dimensional photonic crystal, where the reflective layer includes a reflective region (650) and a non-reflective region (660), where the reflective layer has a bottom surface (622) in contact with the substrate, and a top surface (621). The reflective region has a second angle of incidence (652) between the incident radiation and the normal incidence (653) for the reflective region, such that the reflective radiation (651) is reflected towards the wafer. The reflectivity of the radiation in the reflective region (651) is at least 100 times greater than the reflectivity of radiation in the non-reflectivity region (661). The mask can also include a capping layer (630). The non-reflective region may be similar to the reflective region except that it may be filled with a second material, or be made of a difference second material and be highly absorbing.

Useful 3-dimensional reflective photonic crystals for the present disclosure are described in U.S. Pat. No. 9,322,964. The material can include features that can be used in applications that require operation at one or more electromagnetic wavelength range. In one embodiment, the dimension of structural features is approximately in the same order as the wavelengths used in extreme ultraviolet applications. For example, the structural features can have a dimension of approximately 13.5 nm. In some embodiments, the features can be structural features having dimensions in the order of 10 to 20 nm. In some embodiments, the material can have structural features in the range of 0.001 nm to 10 nm. In some embodiments, the material can have structural features in the range of 10 nm to 250 nm. These features can be referred to as nanoscale features. The nanoscale features can be one dimensional, two dimensional, or three dimensional. The structural features can reduce the bulk electromagnetic absorption of the material. For example, in some applications, the nanoscale features can approximately correlate with the wavelength of the radiation used in that application. The material may include sub-wavelength features.

The materials can also be designed to reduce absorption in applications that use ultraviolet (UV) wavelength range. For example, the dimension of the structural features can correlate to the UV wavelengths. In other embodiments, the dimensions of the structural features can correlate to the soft X-Ray wavelength range. The selected wavelength range can be part of a two or more photon (multiphoton) process which replaces the UV, EUV or X-ray range.

The nanoscale features can include, for example, a periodic or semi-periodic, quasi-periodic or aperiodic structure or a repeating or repeated element. The periodic structure can be a one, two or three dimensional structure. The structure can be part of a layered structure, or on a substrate. The substrate can be planar. Examples of a periodic structure include a 2D or 3D array of nanoparticles, a gyroidal structure, spheres, cylinders, segments, a swiss-roll structure. The nanoscale features can be of any shape in any dimension, for example, but not limited to, layers, films, spheres, blocks, pyramids, rings, porous structures, cylinders, linked shapes, shells, freeform shapes, chiral structures, hemispheres, segments or any combination thereof.

The material can include, for example, a graded structure. For example a layered structure in any dimension where some layers within the material have lengths, depths, thicknesses, periods or repeating units, that increase or decrease from the previous layer. In one embodiment if the layers are arranged in such a way to produce a graded refractive index, then a customized optical response is produced for a broader range of wavelengths or angles. The structure can be part of a layered structure, or on a substrate.

In some embodiments, the 3-dimensional reflective photonic crystal can include gaps or voids, or be porous. The gaps or voids can be of any shape. The gaps or voids can be distributed throughout the material in any dimension and can have sizes ranging from 0.01 nm to micron sizes. The gaps or voids can be filled with a fluid, a liquid gas, monatomic material, organic material, polymer or vacuum. The material may include membranes, free standing structures or elements, or partially supported structures or features, or supporting structure. The features can be supported by structures or components. The gaps can be periodic or random in distribution. The gas may include O₂, Hz, He, N₂, Ar, CO₂ or other gases including non-inert gases. An example is a 3D periodic array of metallic spheres with air gaps. If the system is under vacuum, then the voids can also include vacuum.

The material can further include micro or nano structural features of the monatomic material. Some examples of the monatomic material include graphene, graphite, molybdenum sulphide, and carbon nanotubes. The monatomic material may serve as an optical element or a heat management or cooling mechanism element. The monatomic material can be used in combination with other materials e.g. a metal, dielectric, semiconductor. It can form part of a layered structure, periodic structure, multidimensional or freeform structure, or be on a substrate.

The material can be an organic material or a biomaterial. The material may further comprise micro or nano structural features of the organic or bio material. Examples of organic materials or biomaterials, include DNA, proteins, or other molecular or genomic material which have lower absorption in the wavelengths. The organic material or biomaterial may also be a sacrificial material, or a soft templating or scaffolding structure. The organic or bio material can be encapsulated in other material, which include, but not exclusively, polymers or dielectrics or semiconductors. The organic or bio material may serve as an optical element or a heat management or cooling mechanism element. The organic or bio material can be used in combination with other materials e.g. a metal, dielectric, semiconductor. It may form part of a layered structure, periodic structure, multidimensional or freeform structure, or be on a substrate.

The material can also include a polymer. The material may further comprise micro or nano structural features of the polymer. The polymer may also be a sacrificial material, or a soft templating or scaffolding structure. In some embodiment, the polymer can be removed, leaving gaps or voids in the material. These gaps or voids may form structural features in the material. In other embodiments, the polymer can remain in the material. The polymer can be photoresist. The polymer may also be irradiated and exposed by a laser or a two or more photon laser process.

The material may include nanoscale features that are made using metals, semiconductors, alloys, dielectrics, compounds, gases, liquids or combinations of these. These nanoscale structures can be engineered to reduce absorption by the material at one or more band of wavelengths. The metal may include for example gold, silver, platinum, molybdenum, beryllium, ruthenium, rhodium, niobium, palladium, copper, lanthanum. The combined material may include for example silicon, silicon dioxide, boron carbide, carbon, organic, biomaterial, germanium, polymers or monatomic materials, liquids or gases or other element, alloy or compound, or vacuum. In this case, a either material can have a small amount of absorption as described by the imaginary part of the refractive index, where one material has more than the other.

The material may have nanosized structures and features which form an array or are periodic in one, two or three dimensions, for example, but not limited to, a photonic crystal, plasmonic crystal, metamaterial, chiralic structure or sub-wavelength structure. Features of the array can be tuned to optimize the wavelength, spectral bandwidth, photonic bandgap angular acceptance, reflectance including average reflectance (when averaged over the spectral range), transmission, absorption, scattering and electromagnetic enhancement factor, resonance or interaction modes. The structure may provide a cavity which slows the group velocity of light to increase electromagnetic interaction, or form a waveguide or cavity where certain electromagnetic nodes are enhanced and certain nodes are forbidden. In the case of forbidden modes of propagation, this can be used to form a selective or omnidirectional mirror with tunable peak wavelength and spectral bandwidth properties. The cavity can also be used to enhance the conversion of light from infrared to EUV, as can be needed in a two or more photon process, or a lightsource emitting EUV radiation from infrared excitation e.g. a plasma source.

The nanoscale features of the material may, for example, be configured as a 3D hexagonally packed array. The 3D hexagonally packed array may include a metal. The metal may be, for example, gold, silver, ruthenium, molybdenum, silicon, germanium, or platinum, palladium or other metal.

The nanoscale features of the material may, for example, include a gyroid structure. The gyroid structure can be a metal, for example, gold, silver, ruthenium, molybdenum, silicon, germanium, or platinum.

The nanoscale features of the material may, for example, be made using graphene or molybdenum graphene (Mo-Graphene). The nanoscale features may include a graphene double gyroid structure.

The nanophotonics material may include a periodic one, two or three-dimensional structure engineered to have a low bulk absorption of electromagnetic radiation at selected wavelengths, such as at UV, EUV, or soft X-ray wavelengths. In some embodiments, the 3-dimensional reflective photonic crystal includes a porous metallic structure.

The first metal can include any metal that is reflective to EUV or X-ray radiation, or improves the reflective properties of the reflective regions of the reflective layer. Exemplary metals include, but are not limited to, molybdenum, niobium, molybdenum carbide, technetium, ruthenium, zirconium, or mixtures thereof. In some embodiments, the first metal can be molybdenum, niobium, molybdenum carbide, technetium, ruthenium, zirconium, or mixtures thereof. In some embodiments, the first metal can be molybdenum.

The second metal can include any metal that absorbs or X-ray radiation, or improves the absorbance properties of the non-reflective regions of the reflective layer. Exemplary metals include, but are not limited to gold, silver, nickel, cobalt, copper, platinum, iron, manganese, or mixtures thereof. In some embodiments, the second metal can be gold, silver, nickel, cobalt, copper, platinum, palladium, tantalum, iron, manganese, or compounds, alloys or mixtures thereof. In some embodiments, the second metal can be copper. The non-reflective region may be any oxide or nitride compound.

In some embodiments, the first metal can be molybdenum, niobium, molybdenum carbide, technetium, ruthenium, zirconium, or mixtures thereof, and the second metal can be gold, silver, nickel, cobalt, copper, platinum, iron, manganese, or mixtures thereof. In some embodiments, the first metal can be molybdenum, niobium, molybdenum carbide, technetium, ruthenium, zirconium, or mixtures thereof, and the second metal can be gold, silver, nickel, cobalt, copper, platinum, iron, manganese, tantalum, tantalum oxide, tungsten, aluminum, palladium, platinum, or alloys or mixtures or compounds thereof. In some embodiments, the first metal can be molybdenum and the second metal can be gold.

The first metal and second metal can be present in the reflective layer, in the reflecting and non reflecting regions respectively, in any suitable amount to achieve an image contrast of at least 100.

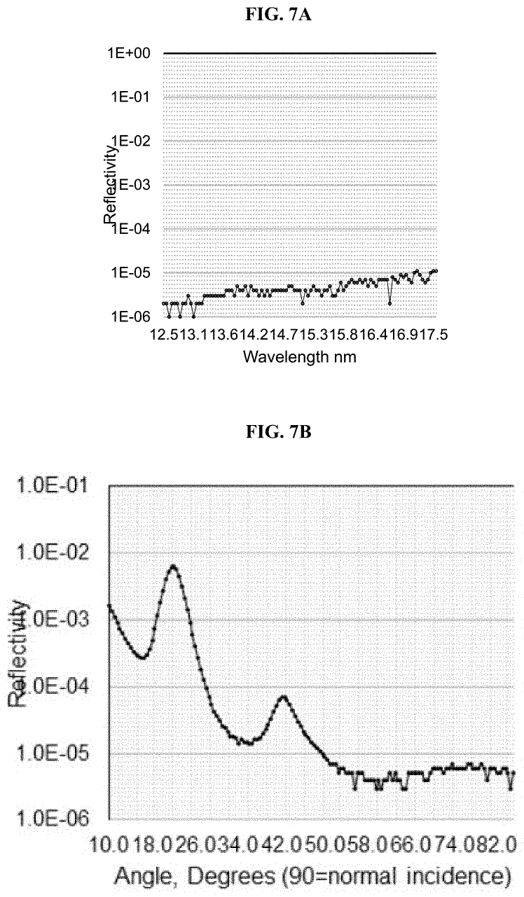

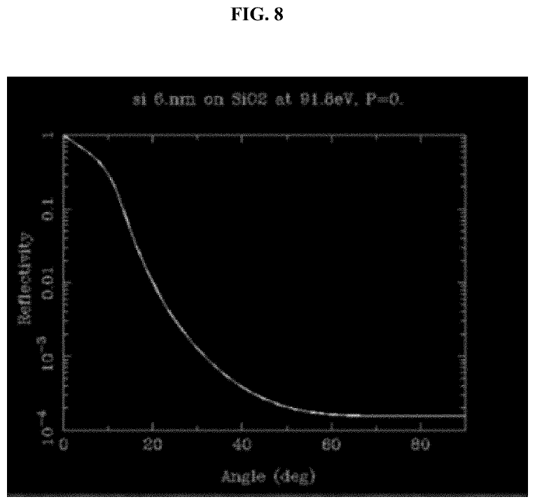

The non-reflecting region may simply be the material from the reflecting region, filled in with an additional secondary material. Since Reflectivity is close to 10⁻⁵ to 10⁻⁶ (FIG. 7A) at 13.5 nm for most angles within +/−30 degrees from normal incidence, any light entering the region is largely absorbed. (FIG. 7B).

The 3-dimensional reflective photonic crystals of the present disclosure can be prepared according the procedures described in U.S. Pat. No. 9,322,964.

A process for making a 3D non-reflective region may be:
1) Create photomask architecture, deposit 3D metallic or non metallic reflective coating on substrate (described in other patents), optionally followed by capping layer, e.g. Ruthenium.
2) Coat top surface with photoresist or e-beam resist, e.g. through spin coating, dip coating or other
3) Use e-beam or optical lithography direct write to pattern photoresist into reflecting and non reflective regions (patterned resist in non reflecting regions, representing IC pattern
4) Deposit absorbing material into non reflective regions e.g. by atomic layer deposition, sputtering, chemical vapor deposition, e-beam deposition, ion beam deposition, ion implantation, ion assisted deposition, physical vapor deposition, pulsed laser deposition,
5) Remove photoresist or e-beam resist.
6) Planarize surface via chemical mechanical polishing
7) Optionally deposit ruthenium capping layer if not deposited in 1)

FIG. 7A shows the experimental reflectivity data of the non reflective region, which is of the order 10-5 at near normal incidence. The 3D structure of the non reflective region has a high internal surface area and is highly absorbing. The reflectivity is several orders of magnitude lower than the reflective region. In some embodiments it is at least 3 orders of magnitude lower than the reflective region which has a reflectivity of 67% or higher, providing 100× greater image contrast.

FIG. 7B shows the experimental angular spectrum data of the reflectivity in the non reflective region.

### D. Additional Mask Embodiments

The EUV mask of the present disclosure can include additional layers. In some embodiments, the EUV mask can also include a capping layer in contact with the top surface of the reflective layer. The capping layer can be prepared from any suitable material to protect the reflective layer and that is transparent to the EUV and X-ray radiation. Representative materials for the capping layer include ruthenium and any other transition metal. In some embodiments, the capping layer includes ruthenium.

The capping layer can be of any suitable thickness. For example, the capping layer can be from 1 to 100 nm thick, or from 1 to 10 nm thick. The capping layer can have a thickness of about 1 nm, or about 2, 3, 4, 5, 6, 7, 8, 9, or about 10 nm. In some embodiments, the capping layer can have a thickness of about 5 nm.

Use of a non-reflective region in the reflective layer avoids the need for an absorbance layer on top of the reflective layer. In some embodiments, the present disclosure provides an EUV mask wherein an absorbance layer is not present. In some embodiments, the present disclosure provides an EUV mask substantially free of an absorbing layer. In some embodiments, the present disclosure provides an EUV mask substantially free of tantalum nitride.

A pellicle, if necessary, may be attached directly to the top surface of the EUV mask, or in close proximity of the top surface, and conformally to plane of a photomask containing a submerged non reflecting region. Compared to the state of the art where the absorber plane is above the multilayer plane, the pellicle as applied to the present disclosure completely prevents particles entering the photomask on the reflective region. The pellicle may be vertically integrated as part of the full mask architecture.

The pellicle may be charged to deflect particles from landing on the pellicle or the mask.

The etched multilayer may optionally be filled with SiO2 instead of Si, as this is more absorbing and worsens reflectivity.

After etching the non reflective region, the top level of the multilayer in non reflecting region is silicon or silicon dioxide (from oxidation). This reduces reflectivity further.

Roughness degradation may be used to reduce reflectivity further, e.g. by etching of the top layer or pitting with defects can also increase scattering and worsen reflectivity in the 0th order. The this can also be achieved by filling the non reflective region with small nanoparticles which add roughness or by increasing the high frequency component of surface roughness.

Nanostructured surfaces, including faceted angles in the non reflective region can sometimes have a self cleaning effect, where the particles cannot easily deposit or attach to the surface, or it is not energetically favorable for them to do so, and so are easily removed.

A pellicle, if necessary, may be attached directly to the top surface, or in close proximity of the top surface, and conformally to plane of a photomask containing a submerged non reflecting region. Compared to the state of the art where the absorber plane is above the multilayer plane, the pellicle as applied to the present disclosure completely prevents particles entering the photomask on the reflective region. The pellicle may be vertically integrated as part of the full mask architecture.

The pellicle may be charged to deflect particles from landing on the pellicle or the mask.

In some embodiments, the present disclosure provides a photomask component configured to be used in a light system. The light system comprises a light source configured to transmit light having a wavelength in the range 0.1 nm to 250 nm. The photomask comprises a reflective layer or multilayer or reflective coating, and/or the photomask comprises one or more non reflective regions within the reflective coating and/or below the surface of the reflective coating.

In some embodiments, the present disclosure provides a method to fabricate a non reflective region in a reflective photomask. The reflective photomask comprises a substrate; a reflective layer on top of a substrate; and an optional capping layer on top of a reflective layer. The method comprises the steps of an e-beam writing a pattern to distinguish reflective and non reflective layers; and etching of the multilayer in the non reflective regions to a depth below the top surface and within the multilayer before reaching the substrate.

In some embodiments, the present disclosure provides a method to fabricate a non reflective region in a reflective photomask. The reflective photomask comprises a substrate; a reflective layer on top of a substrate which comprises a photonic or plasmonic structure; and an optional capping layer on top of a reflective layer. The method comprises the steps of an e-beam writing a pattern to distinguish reflective and non reflective regions; and depositing an alternative material into the non reflective region to the material below the reflective region.

In some embodiments, the present disclosure provides a method to fabricate a non reflective region in a reflective photomask. The reflective photomask comprises a substrate; a reflective layer on top of a substrate; and an optional capping layer on top of a reflective layer. The method comprises the steps of an e-beam writing a pattern to distinguish reflective and non reflective regions; and an e-beam writing a diffraction grating in the non-reflecting region.

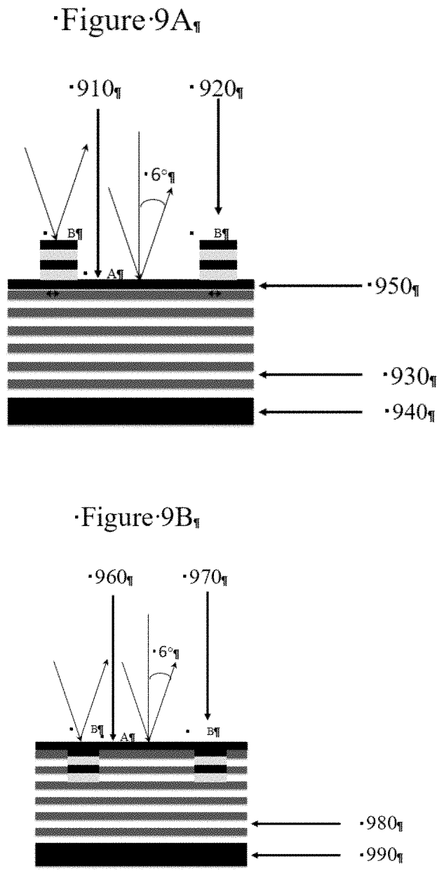

Another embodiment of this disclosure is a phase shift mask. In this embodiment the reflecting and non reflecting regions are replaced by reflecting in and reflecting out of phase regions, or reflecting regions (A) (910) and phase shifted reflecting regions (B) (920) that have reflected light that is phase shifted with respect to the phase of region A. The phase shifted region may also have light that is phase shifted with respect to the incident light. See FIG. 9A and FIG. 9B. The phase shift may be 180 degrees, also known as Pi radians (3.1415) out of phase, or the phase shift may be more or less than 180 degrees by an desired quantity. A non integral value of the phase shift e.g. 1.2 Pi or 1.25 Pi but not limited to those values, may also be used. This may be used in an EUV mask to create a phase shifted mask. The phase shifted mask is similar to the amplitude mask, but uses adjacent phase shifted regions to achieve the desired amplitude cancellation.

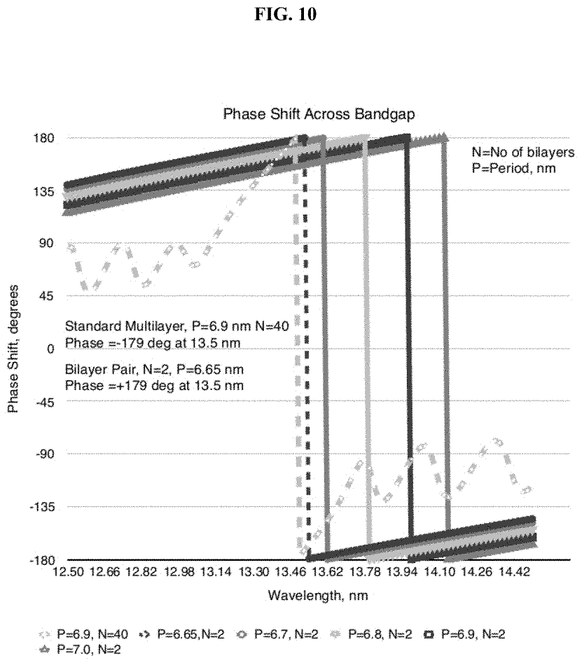

In this embodiment there may be no absorber layer used. Instead, a phase shifted region with a specific phase shift within the reflective coating is created. The phase shifted region is tuned to produce the desired amount of phase shift to cancel out the reflected light in the region adjacent to it. In a typical state of the art alternating phase mask, thicker and thinner absorber layer regions are used to create a phase shifts of the reflected light. However, in this embodiment a desired phase shift is created by taking advantage of the +/−180 phase change across the reflectivity bandgap in the reflective coating, and shifting the bandgap seen by the light accordingly to create a specifically desired phase shift. In a reflective multilayer embodiment shifting the bandgap is achieved by creating adjacent bilayers or multilayers reflective regions (B) with a different period to main reflective multilayer coating (A). A slightly larger period will produce a negative phase shift. A smaller period will produce a positive phase shift. The change in period corresponds to the phase shift desired in the adjacent region. A phase shift as large as +180 degrees or −180 degrees (or +179 degrees and −179 degrees) can be produced. FIG. 10 shows a shifted bandgap in a reflective multilayer embodiment. The change in period corresponds to the phase shift desired in the adjacent region. The phase shifting region may consist of a single bilayer (of two layers, each layer of a different material), two bilayers or may consist of many bilayer pairs, also known as a multilayer. The bilayer pair may be made of the same materials as the main reflective multilayer or of a different materials. There may be more than one bilayer in the phase shifted region. The advantage of the phase shift multilayer is that the total height of the collection of bilayers is less than that of a single absorber layer and achieves the same effect. Almost any desired phase shift (from −180 degrees to +180 degrees) can be achieved either by independently changing the number of bilayer pairs, or by slightly shifting the period of bilayer pair (total thickness of the two materials) compared to the period in the reflective region of the multilayer) or by changing the relative thickness ratio or refractive index ratio of the two layers in the bilayer pair compared to the multilayer, or by changing the order of the two materials, or by changing the material combination. Any combination of these can also be used. For example FIG. 10 shows an n=2 bilayer pair (i.e., two bilayers, a total of 4 layers), with a period of 6.65 nm producing the opposite phase of an multilayer consisting of 40 bilayer pairs with a 6.9 nm period of the same material at a wavelength of 13.5 nm. This means that the total phase shift can be achieved using a phase shifting reflective region with a total finite height of 13.3 nm. Similarly FIG. 10 shows a phase shift (from −179 degrees to +162 degrees) can be achieved keeping the same period, but changing the number of bilayer pairs from 40 to 2.

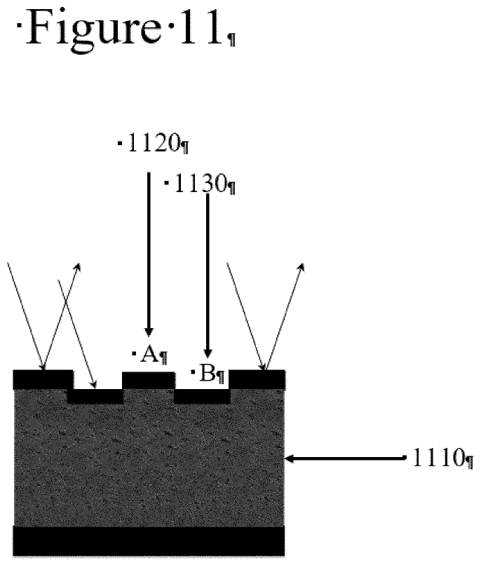

In a non multilayer embodiment, a desired phase shifted is also created by creating an adjacent region with an increased or decreased periodicity from the periodicity of the main reflective coating (1110). In a non-multilayer embodiment, such as a single multidimensional coating (1110), a phase shifted region can also be created using the same coating (similar to the coating in FIG. 6), but slightly changing the thickness at the top of coating in that region. (1130) FIG. 11.

The adjacent phase shifting regions can be created by a combination any of the following techniques of e-beam lithography, optical lithography etch, ion beam or sputtering deposition, lift-off lithography, etch-stops and planarization. The phase shifted region may also be placed above the reflecting region or multilayer. For example one method of fabrication may involve depositing a multilayer reflective coating on a substrate (940), followed by a capping layer. Then, the method may involve depositing a set of one or more bilayer pairs on top of the capping layer which may be of a different period to the first multilayer. The bilayer pairs are then patterned by e-beam lithography and then etched down to the capping layer surface (950) or other etch stop. (FIG. 9A) Another method may be to pattern a reflective multilayer with e-beam lithography, etching partially into multilayer coating, then depositing a second set of bilayer pairs of different period, followed by lift-off lithography and planarization, and deposition of a capping layer. (FIG. 9B)

In embodiments disclosed herein, the non reflecting regions or the phase shifted reflecting regions are within a few wavelengths of the top surface. Particular embodiments disclosed herein do not have exclusive absorber layers. Capping layers (950) and interfacial barrier layers or protective layers may still be used in these embodiments.

### EXAMPLES

### Example 1. Preparation of Facets

A process for making a faceted angle may be:

1) Create an EUV mask architecture by deposited reflective coating on substrate, optionally followed by capping layer, e.g. Ruthenium.
2) Coat top surface with photoresist or e-beam resist, e.g. through spin coating, vapor deposition, spraying or dip coating.
3) Use e-beam or optical lithography direct write to pattern photoresist into reflecting and non reflective regions, representing IC pattern
4) Use etching process to create a facet angle in the underlying reflective coating, e.g. tilted reactive ion etch i.e. etching with a tilted substrate, anisotropic or voltage bias etch, or etching followed by wide angle deposition, or deposition with a tilted substrate
5) Optionally deposit silicon or ruthenium
6) Remove photoresist or e-beam resist.
7) Optionally planarize top surface by chemical mechanical polishing is silicon is deposited
8) Optionally deposit ruthenium capping layer if not deposited in 1).

### Example 2. Preparation of Functional 3-D Photonic Crystal

A process for making a 3D non-reflective region may be:
1) Create photomask architecture, deposit 3D metallic or non metallic reflective coating on substrate (described in other patents), optionally followed by capping layer, e.g. Ruthenuim.
2) Coat top surface with photoresist or e-beam resist, e.g. through spin coating, dip coating or other
3) Use e-beam or optical lithography direct write to pattern photoresist into reflecting and non reflective regions (patterned resist in non reflecting regions, representing IC pattern
4) Deposit absorbing material into non reflective regions e.g. by atomic layer deposition, sputtering, chemical vapor deposition, e-beam deposition, ion beam deposition, ion implantation, ion assisted deposition, physical vapor deposition, pulsed laser deposition,
5) Remove photoresist or e-beam resist.
6) Planarize surface via chemical mechanical polishing
7) Optionally deposit ruthenium capping layer if not deposited in 1).

Although the foregoing disclosure has been described in some detail by way of illustration and Example for purposes of clarity of understanding, one of skill in the art will appreciate that certain changes and modifications may be practiced within the scope of the appended claims. In addition, each reference provided herein is incorporated by reference in its entirety to the same extent as if each reference was individually incorporated by reference. Where a conflict exists between the instant application and a reference provided herein, the instant application shall dominate.

1. An extreme ultraviolet mask, comprising:
a substrate; and
a reflective layer comprising a reflective region and a non-reflective region within the reflective layer, wherein the reflective layer comprises a bottom surface in contact with the substrate, and a top surface, wherein the reflectivity of radiation in the reflective region is at least 100 times greater than the reflectivity of radiation in the non-reflective region;
wherein the radiation has a wavelength from 250 nm to 1 nm.

2-7. (canceled)

8. The mask of claim 1, further comprising an angular faceted structure, wherein the surface normal of the angular faceted structure is at least 6 degrees to the surface normal of the reflective region.

9. The mask of claim 1, wherein the reflectivity, optical response is detuned away from the peak resonance, by periodic changes, angular changes or fill factor.

10. The mask of claim 1, wherein absorption is achieved by a non-reflecting layer within the reflective layer, below the plane of the surface, such that no absorber layer is present.

11. The mask of claim 1, wherein the reflective coating is a multilayer coating.

12. The mask of claim 1, wherein the coating comprises molybdenum, niobium, or ruthenium.

13.-15. (canceled)

16. The mask of claim 8, wherein the facet comprises a first angle of incidence that is greater than a second angle of incidence for the reflective region.

17. The mask of claim 16, wherein the first angle of incidence is greater than 6 degrees from the normal incidence for the reflective region.

18. (canceled)

19. The mask of claim 16, wherein the facet angle is at least 20 degrees below the top surface of the reflective layer.

20. (canceled)

21. The mask of claim 16, wherein the reflective layer comprises multilayers of molybdenum and silicon, or ruthenium, niobium, technetium, boron carbide, or tungsten and carbon.

22. (canceled)

23. The mask of claim 33, wherein the facet is filled with a transparent material so that the top surface of the reflective layer is substantially planar, and wherein the transparent material comprises silicon, silicon dioxide, aluminum, boron carbide, aluminum, strontium, or mixtures thereof.

24. (canceled)

25. The mask of claim 1, wherein the non-reflective region comprises a diffraction grating at the top surface of the reflective layer, and wherein the diffraction grating is embedded within or on top of the non-reflective region.

26.-27. (canceled)

28. The mask of claim 25, wherein the diffraction grating is one-dimensional, two-dimensional or three-dimensional, and wherein the diffraction grating comprises at least one component selected from the group consisting of cobalt, copper, nickel, gold, copper, tungsten, tantalum oxide and tungsten oxide.

29.-32. (canceled)

33. The mask of claim 1, wherein the reflective layer comprises a 3-dimensional reflective photonic crystal, wherein the reflective region comprises a first metal, and wherein the non-reflective region comprises a second metal.

34. The mask of claim 33, wherein the 3-dimensional reflective photonic crystal comprises a porous metallic structure.

35. The mask of claim 33, wherein the first metal comprises molybdenum, niobium, molybdenum carbide, technetium, ruthenium, zirconium, or mixtures thereof, and wherein the second metal comprises gold, silver, nickel, cobalt, copper, platinum, iron, manganese, or mixtures thereof.

36.-39. (canceled)

40. The mask of claim 1, wherein the mask is substantially free of an absorbing layer.

41. (canceled)

42. A photomask component configured to be used in a light system, wherein:
a. the light system comprises a light source configured to transmit light having a wavelength in the range 0.1 nm to 250 nm;
b. the photomask comprises a reflective layer or multilayer or reflective coating; and
c. the photomask further comprises one or more non non-reflective regions within the reflective coating and or below the surface of the reflective coating.

43. A method to fabricate a non-reflective region in a reflective photomask of claim 42, wherein the reflective photomask comprises:
a substrate;
a reflective layer on top of a substrate; and
an optional capping layer on top of a reflective layer; and
wherein the method comprises:
e-beam writing a pattern to distinguish reflective and non-reflective layers; and
etching of the multilayer in the non-reflective regions to a depth below the top surface and within the multilayer before reaching the substrate.

44. A method to fabricate a non-reflective region in a reflective photomask of claim 42, wherein the reflective photomask comprises:
a substrate;
a reflective layer on top of a substrate which comprises a photonic or plasmonic structure; and
an optional capping layer on top of a reflective layer; and
wherein the method comprises:
e-beam writing a pattern to distinguish reflective and non-reflective regions; and
depositing an alternative material into the non-reflective region to the material below the reflective region.

45. A method to fabricate a non-reflective region in a reflective photomask of claim 42, wherein the photomask comprises:
a substrate;
a reflective layer on top of a substrate; and
an optional capping layer on top of a reflective layer; and
wherein the method comprises:
e-beam writing a pattern to distinguish reflective and non-reflective regions; and
e-beam writing a diffraction grating in the non-reflecting region.

46. An extreme ultraviolet mask, comprising:
a substrate; and
a reflective layer comprising a reflective region and a phase shifted reflective region relative to the reflective region located within or above the reflective layer, wherein the reflective layer comprises a bottom surface in contact with the substrate, and a top surface.

47. The extreme ultraviolet mask of claim 46,
wherein the phase shifted reflective region consists of one or more bilayer pairs.

48. The extreme ultraviolet mask of claim 46,
wherein the phase shifted reflective region consists of one or more bilayer pairs and is of a slightly different period compared to bilayer pairs or multilayers in the reflective region.
